(19) United States
(12) Patent Application Publication
(10) Pub. No.: US 2012/0258862 A1
(43) Pub. Date: Oct. 11, 2012

(54) OPEN-BORE MAGNET FOR USE IN MAGNETIC RESONANCE IMAGING

(75) Inventors: Feng Liu, Forest Lake (AU); Riyu Wei, Forest Lake (AU); Stuart Crozier, Wilston (AU)

(73) Assignee: NMR HOLDINGS NO. 2 PTY LIMITED, Milton, Queensland (AU)

(21) Appl. No.: 13/518,117

(22) PCT Filed: Dec. 20, 2010
(86) PCT No.: PCT/AU2010/001714

§ 371 Date: Jun. 21, 2012

(30) Foreign Application Priority Data
Dec. 21, 2009 (AU) 2009906199

(51) Int. Cl. G01R 33/3815; G01R 33/035

(52) U.S. Cl. 505/162; 324/318

(57) ABSTRACT

A magnetic resonance system is provided which employs a shielded, electromagnetically asymmetric and low-stress magnet to produce a superior sized imaging region close to the patient side. The magnet has a double layered configuration. In the primary layer, the magnet includes at least two strongest coils at two ends of the magnet (end coils), which carry current in the same direction. The magnet may include at least one coil close to the end coils which carries current in a direction opposite to that of the end coils. The magnet employs a plurality of smaller sized coils (4-7, relative to the large end-coils) in the central region of the primary layer, and these coils are located asymmetrically relative to the imaging region centre. The magnet is shielded by a plurality (1-5) of shielding coils, which carry current in a direction opposite to that of the end-coils at primary layer. Compared with conventional short-bore magnets, the magnet of the invention offers an accessible imaging region with significantly enlarged imaging region, and it can be used in, for example, body-part or whole-body imaging.

### FIELD OF THE INVENTION

This invention relates generally to magnets for producing magnetic fields for use in magnetic resonance imaging [‘MRI’] applications. In particular, the invention is directed to effectively short, shielded asymmetric superconducting magnets for producing substantially homogeneous magnetic fields (B₀ fields) for use in MRI applications, although the invention is not limited thereto. Such magnets are well-suited for use in both whole body magnetic resonance imaging and in specialist magnetic resonance imaging such as for use in producing images of joints and other extremities of a subject.

### BACKGROUND OF THE INVENTION

Magnetic resonance imaging was introduced in the 1980s, and has developed into a major global imaging modality with current sales of approximately 3,000 scanners worldwide per annum.

Clinical MRI depends for its success on the generation of strong and pure magnetic fields. A major specification of the static field in MRI is that it has to be substantially homogeneous over a predetermined imaging region, known in the art as the “diameter spherical imaging volume” or “dsv.” Errors less than 20 parts per million peak-to-peak (or 10 parts per million rms) are typically required for the dsv.

MRI equipment has undergone a number of refinements since the introduction of the first closed cylindrical systems. In particular, improvements have occurred in quality/resolution of images through. improved signal to noise ratios [‘SNR’] and introduction of high and ultra high field magnets. Improved resolution of images, in turn, has led to MRI being a modality of choice for an increasing number of specialists for both structural anatomical and functional human MRI imaging.

The basic components of a typical magnetic resonance system for producing diagnostic images for human studies include a main magnet (usually a superconducting magnet which produces the substantially homogeneous magnetic field [the B₀ field] in the dsv), one or more sets of shim coils, a set of gradient coils, and one or more RF coils. Discussions of MRI, can be found in, for example, Haacke et al., Magnetic Resonance Imaging: Physical Principles and Sequence Design, John Wiley & Sons, Inc., New York, 1999. See also Crozier et al., U.S. Pat. No. 5,818,319, Crozier et al., U.S. Pat. No. 6,140,900, Crozier et al., U.S. Pat. No. 6,700,468, Dorri et al., U.S. Pat. No, 5,396,207, Dorri et al., U.S. Pat. No. 5,416,415, Knuttel et al., U.S. Pat. No. 5,646,532, and Laskaris et al., U.S. Pat. No. 5,801,609, the contents of which are incorporated herein in their entireties.

Conventional medical MRI magnets are typically around 1.6-2.0 meters in length with free bore diameters in the range of 0.8-1.0 meters. Normally, the magnet is symmetric so that the midpoint of the dsv is located at the geometric center of the magnet's structure. The uniformity of the axial component of the magnetic field in the dsv is often analyzed by a spherical harmonic expansion.

The typical aperture of a conventional MRI machine after the addition of ancillary components (gradients and radiofrequency coils) is a cylindrical space having a diameter of about 0.6-0.8 meters, i.e., just large enough to accept the subject's shoulders, and a length of about 2.0 meters or more. Not surprisingly, many people suffer from claustrophobia when placed in such a space. Also, the large distance between the portion of the subject's body which is being imaged and the end of the magnet system means that physicians cannot easily assist or personally monitor a subject during an MRI procedure. Therefore, there is a need for a short open-bore magnet system in clinical applications.

The challenge in designing such a high-field system is maintaining both the field homogeneity and size of the dsv using the currently available, cost-effective, superconducting technology. The magnet performance is largely related to the bore size in both axial and radial directions. Short or compact magnets are very difficult to design and build. This is mainly because the dense coil structure produced by conventional designs will lead to unacceptable peak field values and stress for the superconducting coil bundles. Normally, an engineering compromise in dsv size has to be made and therefore the imaging quality is not maintained.

Short-bore high field closed systems appeared in the early 2000s, and offered small-sized imaging regions for imaging. The shortest cylindrical scanner available in the market is Siemens 1.5 T (Espree) system and it is about 1.05 m (cold-bore), and it has a dsv size of 30 cm which is sufficient for the imaging of many organs. For certain applications, such as whole spine imaging, however, the system's limited dsv in the axial direction might mean that exams take longer than on a standard 1.5 T MRI, and image quality can be distorted during the image combination procedure especially near the edges of the imaging region.

Although there have been improvements in patient comfort through the introduction of vertical open systems in the early 1990s, the technology is still limited by field strength (vertical open system). To enhance patient comfort, acceptance and maintaining a good-quality imaging performance, there is a strong need for the improvement of the magnet technology which can produce short magnet with uncompromised dsv quality (size, field strength and homogeneity).

In addition to its effects on the subject, the size of the magnet is a primary factor in determining the cost of an MRI machine, as well as the costs involved in the sitting of such a machine. Standard 1.5 T MRI whole body scanners, due to their size, weight, fringe field and power needs, demand highly specialised and expensive infrastructure before they can be installed, including development of separate multi-room imaging suites. These requirements mean that in most cases, only larger hospitals or substantial imaging clinics can afford to install such systems and offer MRI as a diagnostic modality to patients.

In order to be used safely, MRI machines often need to be shielded so that the magnetic fields surrounding the machine at the location of the operator are below regulatory agency-specified exposure levels. By means of shielding, the operator can be safely sited much closer to the magnet than in an unshielded system, Longer magnets require more shielding and larger shielded rooms for such safe usage, thus leading to higher costs.

Extremity MRI (which, for the purposes of this application, is also called orthopaedic MRI) is one of the growth areas of the MRI industry, with 20% of all MRI procedures in the United States in 2006 being performed on upper extremities (e.g., arms, wrists, and elbows) and lower extremities (e.g., legs, ankles, and knees) (IMV, 2007). This equates to 5.3 million extremity procedures in 2006, compared with around 110,000 in 1990, when extremity scans made up only 2% of total MRI procedures.

Extremity MRI systems are much smaller than whole-body or conventional MRI systems and are much easier to site, due both to their reduced size and reduced stray fields. They are therefore a low cost solution to the imaging of extremities. As discussed below, extremity imaging is a preferred application for, the magnets of the present invention.

While extremity MRI systems have a number of advantages to the subject and the operator, they represent a challenge in terms of the space available for the various coils making up the magnet and in terms of cooling those superconducting coils. A major difficulty in realizing a superconducting magnet is to produce a large imaging dsv (of the required homogeneity) when the magnet length is reduced, while ensuring the superconducting wires can be used safely and efficiently.

Open systems, which comprise the larger portion of dedicated extremity systems, are constrained by being limited to lower field strengths; the highest field open MRI scanner on the market in 2005 was the Philips 1.0 T system.

The low field nature of the current smaller MM systems on offer is a major disadvantage to their use. According to the American College of Rheumatology, ‘the low-field MRI systems are unable to obtain the SNR of high-field MRI systems for images of similar spatial resolution’. Low field systems generally have longer image acquisition times, which can be problematic for procedures requiring contrast agents, since for extremity procedures, intravenously injected contrast agents can diffuse into the joint fluid in a period of minutes.

An aim of this invention is to provide improved magnets and MRI systems which address these and other challenges of both whole-body and extremity MRI systems.

### SUMMARY OF THE INVENTION

The present invention provides a magnetic resonance system for producing MR images, and a magnet for use in such magnetic resonance systems.

The magnet comprises a primary coil structure having at least five primary coils positioned along an axis, including a first end coil adjacent a patient side of the magnet and a second end coil adjacent a service side of the magnet. (The term ‘patient side’ is used herein to refer to the side or portion nearer the end of the magnet which receives the patient or part thereof for scanning, while the term ‘service side’ is used to refer to the opposite side or portion.)

For ease of reference, this specification refers to a ‘coil’ or to a number of ‘coils’, but it is to be borne in mind that each coil may comprise one or more windings and may be composed of several juxtaposed parts or sub-blocks which are aligned radially or axially. In particular, one or both of the two end primary coils can each comprise a plurality of coil sub-blocks aligned in radial or axial directions if desired.

Typically, the first and second end primary coils are of the same polarity, i.e. they carry current in the same direction, and are the strongest coils in the primary coil structure, i.e. the total current in each end coil is greater than that in each intermediate coil.

In use, the magnet is capable of producing a magnetic field of at least 1.5 tesla, and preferably at least 3.0 tesla, which is substantially homogeneous over a predetermined imaging region or volume (also called the ‘homogeneous region’ or ‘dsv’). Typically, the imaging region has an external surface defined by a computed variation of the longitudinal magnetic field relative to the longitudinal magnetic field at the imaging centre of less than 20 parts per million peak-to-peak.

The stated field strength and homogeneity are intended to mean the design values of field strength and homogeneity.

Preferably, at least one primary coil which is the second coil from an axial end of the magnet is of opposite polarity to the adjacent end coil, i.e. it carries current in the opposite direction to that end coil.

Advantageously, the primary coil structure has an asymmetric electromagnetic configuration. That is, the primary coil structure is not symmetric with respect to the axial centre of the imaging region, and the primary coils on the patient side of the axial centre of the imaging region carry more total current than the primary coils on the service side of the axial centre of the imaging region. Total current means the product of the current by the number of coil turns or windings.

The magnet centre and the imaging centre can be co-incident or not.

Preferably, the cross-sectional dimension of the imaging region in axial direction (Dz) and the shortest distance between the dsv edge and the magnet aperture (d, cold-bore, patient side) satisfies the relationship: Dz/d=1˜2.

An advantage of the magnet of this invention over conventional cylindrical magnet systems is that, in certain embodiments, the ‘short-bore’ only refers to the patient-side, while the service side of the magnet is not restricted in length, and it can be sufficiently large to support the formation of satisfactorily large dsv while keeping the magnet safe (quench minimized) and cost-effective. This design permits high-quality MRI examinations of claustrophobic patients and ease of access to patients during scanning.

In other words, the distance from the magnet aperture (i.e. the end of the magnet on the patient side) to the dsv edge is kept the same as the conventional short-bore system; however, the dsv size in the axial direction can be enlarged by relaxing the magnet length at the service side. Compared with conventional cylindrical systems, the present invention can not only provide higher level of patient acceptance associated with open systems, but also offers significantly improved imaging performance in terms of accessible imaging region. More importantly, the coil structure in this invention is, not as crowded as a conventional magnet system and therefore the magnets are low-stressed and this is an important advantage as it reduces the possibility of stress-induced quenches.

In terms of short-bore designs, for a MRI whole-body scan embodiment, the magnet advantageously has an axial length less than 160 cm, and preferably less than 140 cm;

and this corresponds to conventional 1 m short-bore system from the patient accessibility point of view.

For an extremity imaging embodiment, the magnet advantageously has an axial length less than 70 cm, and preferably less than 60 cm; and this configuration offers superior sized dsv for orthopaedic imaging.

Preferably, the dsv dimension along the radial direction (Dr, diameter) is at least 40 cm for the whole body imaging embodiment, and 10 cm for the extremity imaging embodiment.

A shielding coil structure is preferably provided around the primary coil structure, and comprises at least one shielding coil of greater diameter than the primary coils. The shielding coil structure is located radially outwardly of the primary coil structure, and extends substantially along the total axial length of the magnet The shielding coil(s) carry current in a direction opposite to that of the end coils of primary coil structure. The shielding coil(s) can be of superconducting structure or ferromagnetic structure. The shielding coil(s) can also be used for tailoring the magnetic fields within the dsv.

Preferably; the magnet has at least three central primary coils (excluding the two end coils and the coil(s) of opposite polarity next to the end coil(s)) which extend axially and their internal envelope covers the whole imaging region. The central coils can be grouped or divided for manufacturing and field/stress controlling purposes, without substantially altering their magnetic field contributions.

In another form, the invention provides a method of designing the magnet of the invention described above. The method involves extending the coil structure on the service side axially with respect to the imaging centre, while retaining a compact coil structure on the patient side, to produce an acceptable large dsv while keeping the magnet safe (quench minimized) and cost-effective.

Preferably, force balancing is used in the design of the magnet to minimize the net forces on the coils, and in particular, the end coils in the primary coil structure. In order to implement force balancing in the design procedure, Maxwell forces are included in the error function to be minimized.

The above summary of the invention and certain embodiments are only for the convenience of the reader and are not intended to and should not be interpreted as limiting the scope of the invention. More generally, it is to be understood that both the foregoing general description and the following detailed description are merely exemplary of the invention, and are intended to provide an overview or framework for understanding the nature and character of the invention.

For example, the magnet is not limited to a two-layer coil structure, and a multi-layer coil structure can be used for the producing a half-compact magnet.

Additional features and advantages of the invention are set forth in the detailed description which follows, and in part will be readily apparent to those skilled in the art from that description or recognized by practicing the invention as described herein. Both these additional aspects of the invention and those discussed above can be used separately or in any and all combinations.

The accompanying drawings provide a further understanding of the invention, and are incorporated in and constitute a part of this specification. The drawings illustrate, by way of example, various embodiments of the invention, and together with the description serve to explain the principles and operation of the invention. In the drawings and the specification, like parts in related figures are identified by like numbers.

### BRIEF DESCRIPTION OF THE DRAWINGS

FIG. 1 shows schematically in perspective the magnet configuration and the dsv.

FIG. 2 illustrates the difference between a conventional short-bore magnet and a magnet according to an embodiment of the present invention.

FIG. 3 is a flowchart illustrating a process used to design the magnets of examples 1-3.

FIG. 4 shows schematically the coil configuration and dsv size of a 1.5 T whole-body magnet example.

FIG. 5 shows the stray field outside the whole-body magnet, and particularly the five gauss (5×10⁻⁴ Tesla) contours.

FIG. 6 is a plot showing calculated magnitudes of the total magnetic field within the coils of the whole-body magnet. The strengths of the fields are shown by the gray scales set forth in the figures.

FIG. 7 is a plot showing calculated magnitudes of the total electromagnetic forces within the coils of the whole-body magnet. The strengths of the forces are shown by the gray scales set forth in the figures.

FIG. 8 shows the current distribution along the whole-body magnet (in axial direction)

FIG. 9 is a current density map (CDM) of the whole-body magnet. This is used in determining the initial setting of the coil configuration before optimization. Similar CDM plots were used for the extremity examples.

FIG. 10 shows schematically the coil configuration and dsv size of an 3 T extremity magnet (3 Ta).

FIG. 11 shows the stray field outside the 3 T extremity magnet (3 Ta), and particularly the 5 gauss (5×10⁻⁴ Tesla) contours.

FIG. 12 is a plot showing calculated magnitudes of the total magnetic field within the coils of the 3T extremity magnet (3 Ta). The strengths of the fields are shown by the gray scales set forth in the figures.

FIG. 13 is a plot showing calculated magnitudes of the total electromagnetic forces within the coils of the 3 T extremity magnet (3 Ta). The strengths of the forces are shown by the gray scales set forth in the figures.

FIG. 14 shows the current distribution along the 3 T extremity magnet (3 Ta) (in axial direction).

FIG. 15 shows schematically the coil configuration and dsv size of an 3T extremity magnet (3 Tb).

FIG. 16 shows the stray field outside the 3 T extremity magnet (3 m), and particularly the 5 gauss (5×10⁻⁴ Tesla) contours.

FIG. 17 is a plot showing calculated magnitudes of the total magnetic field within the coils of the 3 T extremity magnet (3 m). The strengths of the fields are shown by the gray scales set forth in the figures.

FIG. 18 is a plot showing calculated magnitudes of the total electromagnetic forces within the coils of the 3 T extremity magnet (3 Tb). The strengths of the forces are shown by the gray scales set forth in the figures.

FIG. 19 shows the current distribution along the 3 T extremity magnet (3 Tb) (in axial direction) for (1): primary layer and shielding layer; (2) primary layer only.

### DETAILED DESCRIPTION OF EMBODIMENTS OF THE INVENTION

A superconducting magnet typically has a primary coil structure comprising an arrangement of coils. The primary coil structure is surrounded by a shielding coil structure or layer, also made up of an arrangement of one or more coils. In its preferred embodiments, the present invention relates to magnetic resonance systems which comprise effectively short superconducting magnets having electromagnetically asymmetric structures and a particular coil arrangement on the primary structure. The coils are illustrated schematically in the drawings.

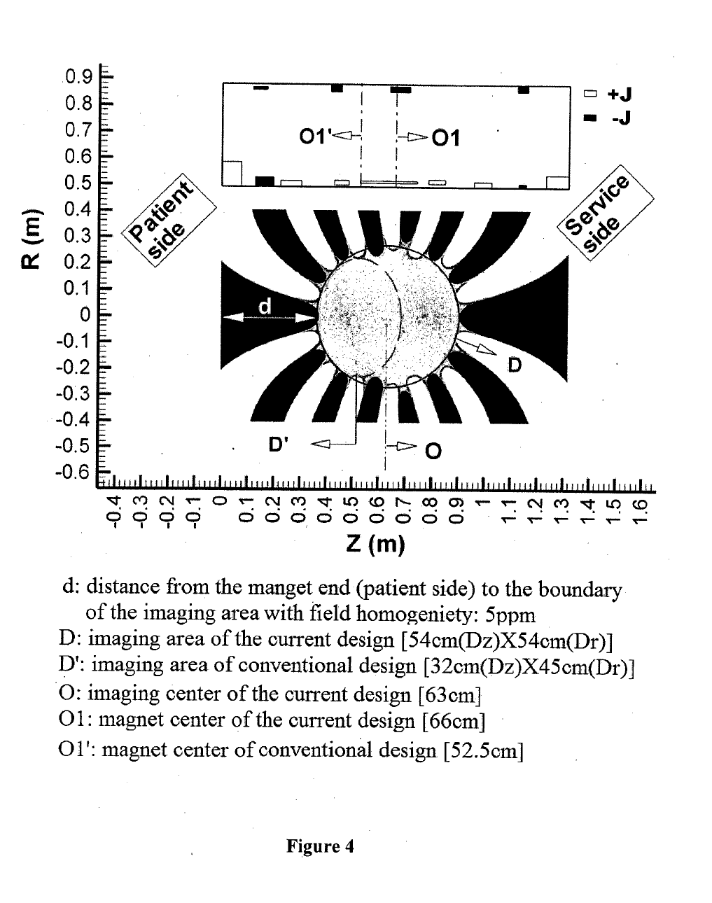

As illustrated, in the embodiments of FIGS. 4, 10 and 15, in the primary coil structure of the magnet, the two end coils are the largest coils (in volume) in the assembly and at least three, and preferably at least four, coils with the same polarity as the end coils are located in the central region of the magnet. At least one coil next to the end coils (patient side) has reverse polarity to other primary coils, i.e. the coil is wound so that current flows in the reverse direction in this coil. This coil assists with improving the homogeneity of the magnetic field within the dsv at that end of the magnet.

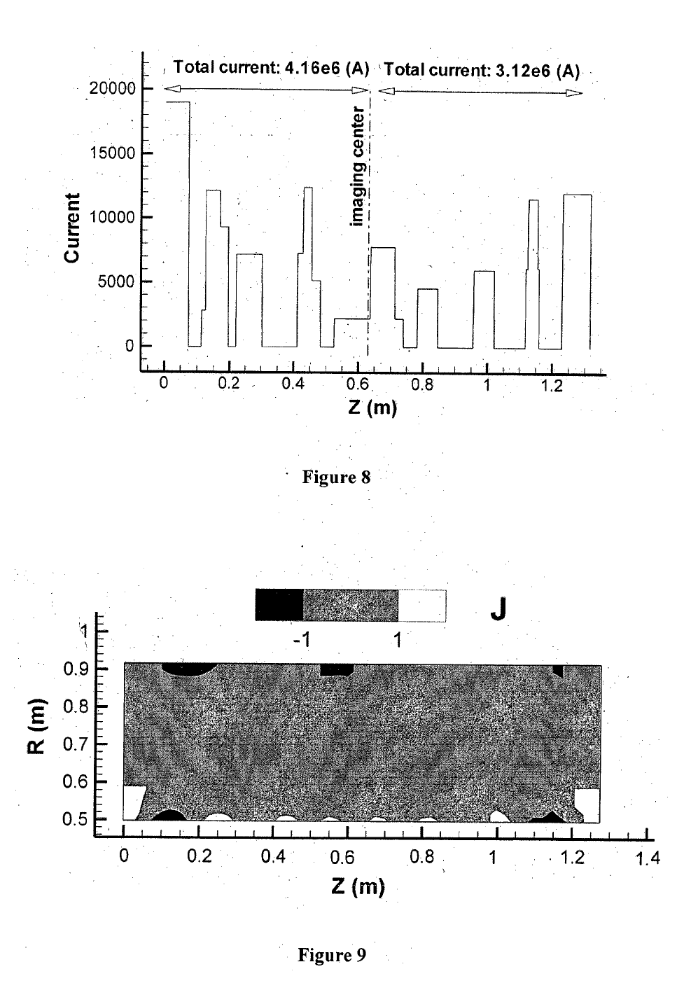

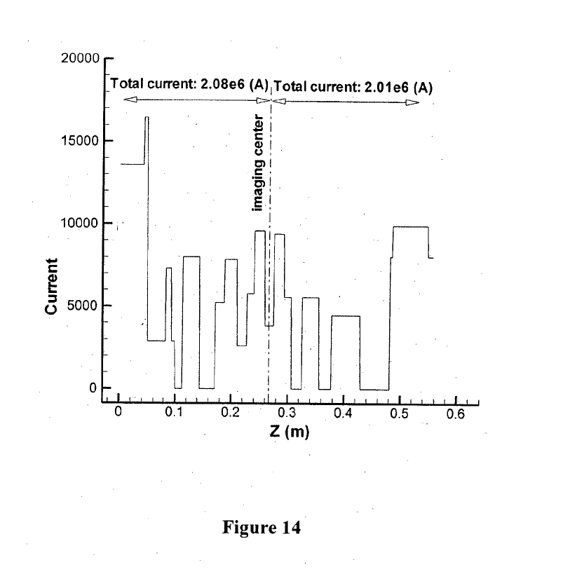

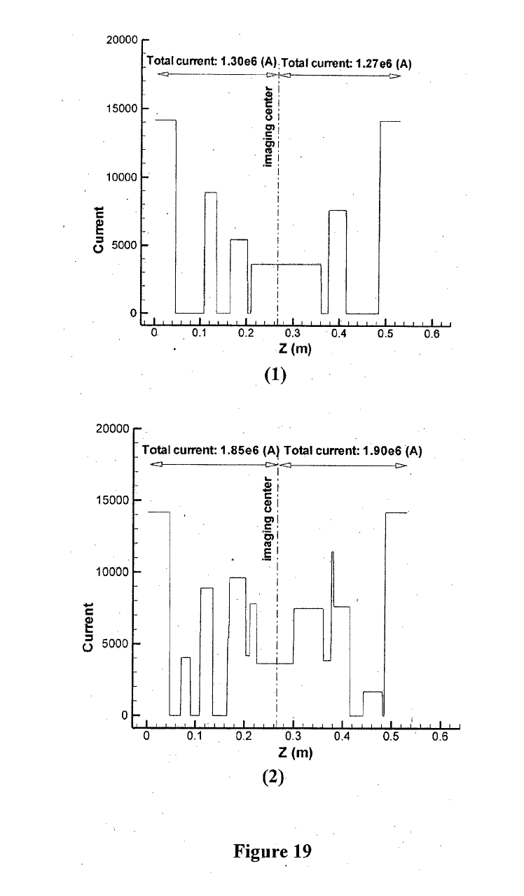

As shown in FIGS. 8, 14 and 19, in the primary coil structure of the magnet, with respect to the imaging centre, the coil pattern on both sides of the assembly is electromagnetically asymmetric, that is the patient side has greater total current than that on the service side.

At the same time, the peak fields in the superconductors are constrained to reasonable values and this is an important practical aspect. If the peak fields are high, the superconductors are restricted in the current density that they can safety carry (or risk quenching—a process in which superconductivity is lost) and furthermore, when the peak fields are high, they require a larger percentage of superconductor filaments within the wire making it more expensive.

Although not wishing to be bound by any particular theory of operation, it is believed that this arrangement of coils allows the magnet to have a large homogeneous dsv relative to the shortest distance between the dsv edge and the magnet end on the patient side. At the same time it leads to peak fields within the superconducting coils of suitable levels to produce safe and efficient magnets.

Instead of a single shielding coil, the shielding layer can include a plurality of separate coils, e.g., two coils or three coils separated over the length of the magnet system. Because the peak magnetic fields and therefore, to some extent, the stresses are controlled in the magnets of the invention, superconducting wires having reduced amounts of superconducting materials, e.g., niobium-titanium alloys, can be used.

In the preferred embodiments of the invention, the magnets achieve some and, most preferably, all of the following performance criteria:

(1) an overall diameter that is less than or equal to 100 cm, and preferably less than or equal to 70 cm, for an extremity imaging magnet, or an overall diameter that is less than 200 cm for a whole body imaging magnet,

(2) an overall length that is less than or equal to 70 cm for an extremity imaging magnet, or an overall length that is less than or equal to 140 cm for a whole body imaging magnet,

(3) a level of dsv homogeneity and size sufficient for effective MR imaging,

(Preferably, at a homogeneity level of 20 parts per million peak-to-peak or better relative to the value of B₀ at the dsv's center, the axial length of the dsv (Dz) and the shortest distance between the dsv edge and the cold-bore magnet end (d) has the relationship: γ=Dz/d is with a range of 1˜2. The small γ corresponds to small imaging area or large accessible distance (equivalently long-bore magnet), the large γ corresponds to large imaging area and/or small accessible distance (effective short-bore magnet). For the whole-body case, the given design has γ=1.48, and the conventional short-bore design γ=0.88<1; for the extremity cases, the two examples have γ=1.51, 1.61, respectively, and the conventional short-bore design γ=0.97<1. This invention does not support γ>2, in that case different electromagnetic feature and coil configurations (e.g., three-layer magnet) will be employed and the dsv will be highly offset towards one magnet end (see U.S. Pat. No. 7,375,528).

(4) sufficient spacing between coils to allow effective cryogenic cooling,

(5) low peak magnetic fields within the coils to allow for the use of less expensive superconducting wire (e.g., a calculated peak magnetic field within any of the plurality of current carrying coils whose magnitude is less than approximately 7.5 Tesla), and

(6) low stray fields (e.g., a calculated stray magnetic field external to the magnet that is less than 5×10⁻⁴ Tesla at all locations greater than 7 m (for whole body system) and 4 m (for extremity system) meters from the dsv geometrical centre).

Examples of the magnets of the invention, and the procedures used in determining the coil configurations and current distribution functions of the magnets, will now be more fully described, without limiting the scope of the invention.

The coil positions were determined in an optimization process (see FIG. 3). The optimization was performed using a constrained numerical optimization technique based on a nonlinear least-square algorithm (Matlab optimization toolbox, http://www.mathworks.com). The routine used the geometry and positions of the field generating elements as parameters and the error terms mentioned above to calculate the final coil geometry for the magnet.

### Example 1 (1.5 T Whole-Body Magnet)

This example, shown schematically in FIG. 4, illustrates a superconducting magnet according to one embodiment of the present invention. In broad overview, the magnet employs thirteen coils and has a cold bore length and a cold bore inner radius of approximately 1.34 and 0.49 meters, respectively. More importantly, the shortest distance between the cold-bore magnet end and the dsv edge is only 0.36 meters, which is difficult to achieve using other coil configurations. In this example, the axial distance between the magnet centre and the imaging centre is 1.2 cm. On the primary windings of the magnet, all of the coils are wound in the same direction (i.e. have the same polarity) apart from the coils second from the ends. These coils are wound in the opposite direction to all others on the primary (i.e. have reverse polarity).

Relative to the imaging centre, the coil blocks on the primary winding have asymmetric electromagnetic topology. The total current on the patient side is essentially greater than that on the service side (see FIGS. 8, 9). This feature, when combined with the topology of the other coils, results in close, improved homogeneity compared to other coil configurations for a magnet offering the same distance d. For comparative purposes, the magnet centre and dsv size of the conventional symmetric short-bore 1.5 T whole body magnet are illustrated in FIG. 4. By keeping d unchanged and relaxing the magnet length on the patient side about 20 cm, the dsv is significantly and beneficially extended in the axial direction from 32 cm to 54 cm (at 5 ppm homogeneity). There are a total of four shielding coils in the shielding coil structure of the magnet, and they extend variously along the length of the magnet.

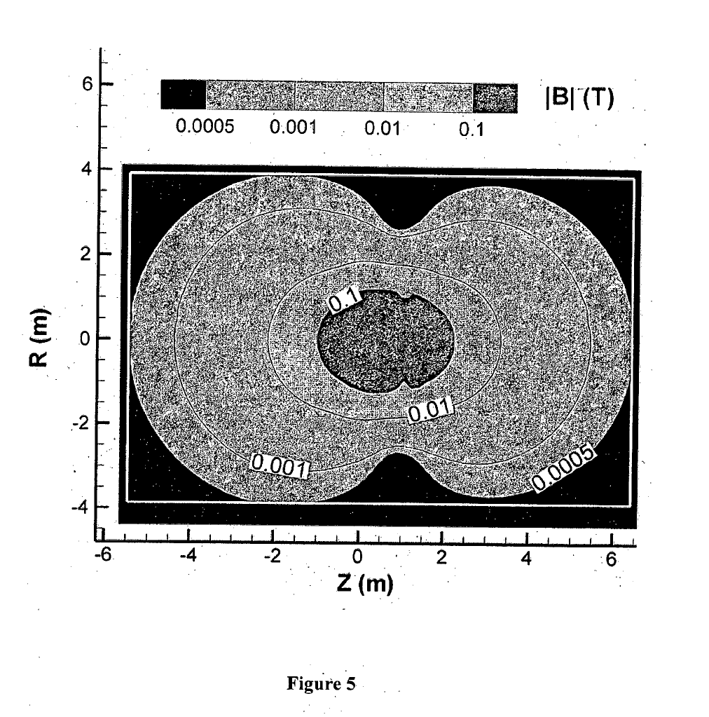

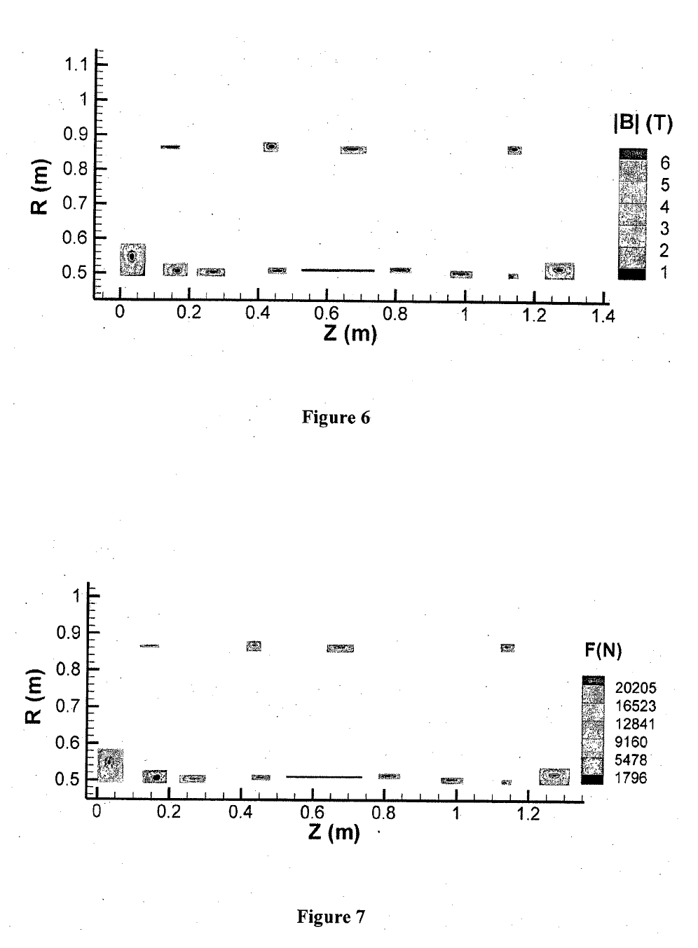

FIG. 4 shows the magnet and the field within the dsv. FIG. 5 shows the calculated stray external fields and axial magnetic field generated by the magnet. FIG. 6 shows the calculated magnitudes of the total magnetic field generated by the magnet within the magnet's various coils. FIG. 7 shows the calculated magnitudes of the total electromagnetic forces generated by the magnet within the magnet's various coils. Note in FIG. 4, the polarities of the current density in each coil are indicated.

As shown in FIG. 4, the magnet has a dsv which is approximately spherical with a diameter of approximately 54 cm, which is a substantial proportion of the total length of the magnet. The magnet also has a 5 Gauss line which is within about 6 meters of the centre of the dsv, being approximately 6 m axially and 4 m radially (shown in FIG. 5).

As shown in FIG. 6, the peak calculated magnetic field is about 6 Tesla, which allows the magnet to be constructed using readily available superconducting wire.

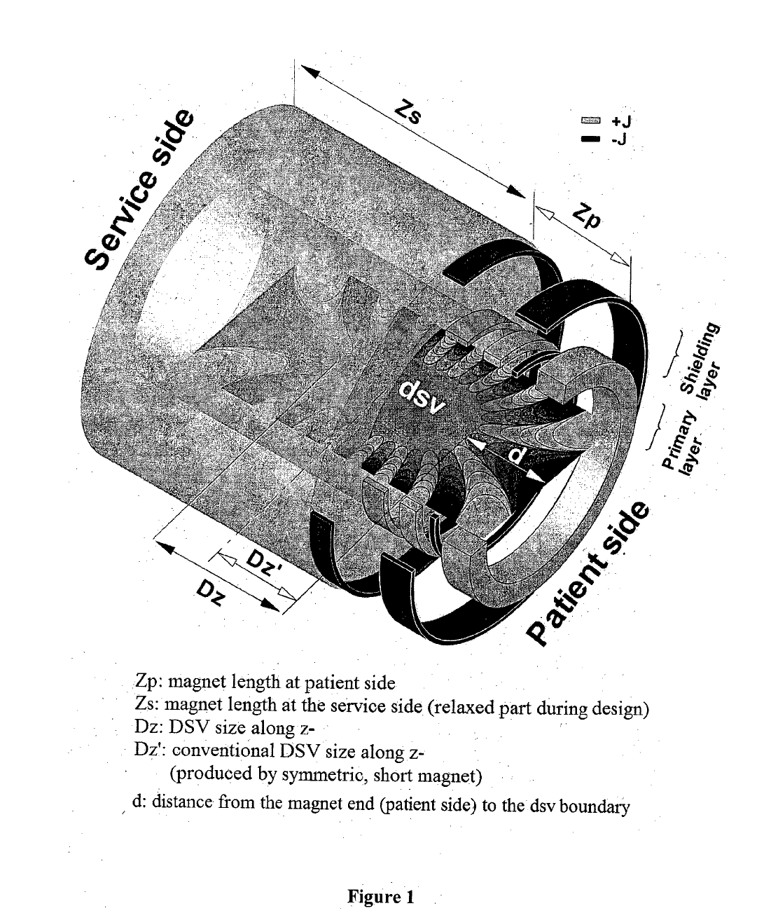

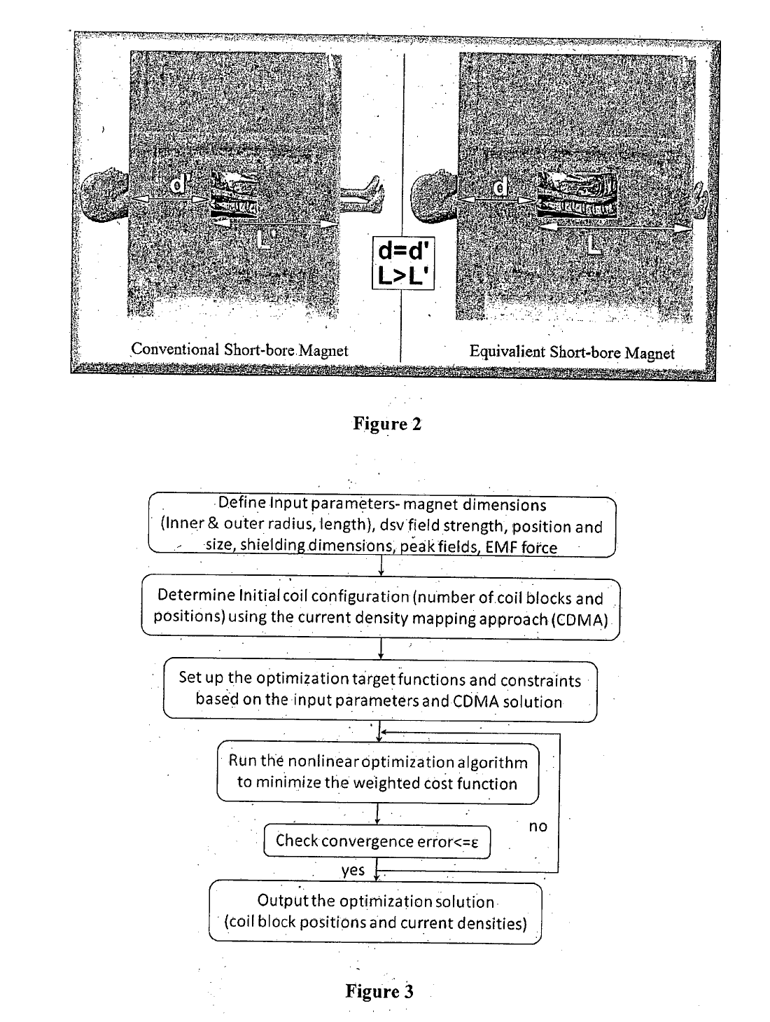

FIG. 1 shows in perspective the relative sizes of the coils and the dsv, indicating a close, large dsv compared to the total magnet length and thus enabling the imaging of whole body, for example, with the patient comfortably positioning on the bed with head outside the magnet during examinations (as shown in FIG. 2). The distance ‘d’ from the edge of the dsv to the patient end of the magnet is 36 centimetres, which is the same as conventional short bore designs. However, in prior art short magnets with constant height, due to the limitation of superconductor wire, high inter-coil and intra-coil stresses/peak fields due to close spacing between coils and reduced cold bore space problems make the magnet difficult to build at reasonable cost. Therefore, a small sized dsv (e.g. 30 cm instead of conventional 40-45 cm in the axial direction) has to be considered for practical usage. This example of the present invention overcomes the technical challenges and produces the imaging region whose size is 1.8 times of the one offered by conventional short-bore technology.

As shown in FIGS. 8 and 9, the primary layer of the magnet has a total current distribution function which is asymmetric with respect to the imaging centre along the longitudinal axis, i.e., the total current on the patient side is larger than that on the service side. The magnets of 3 T extremity examples also have such asymmetric current distribution functions.

### Example 2 (3 T Extremity Magnet (Versions a, b))

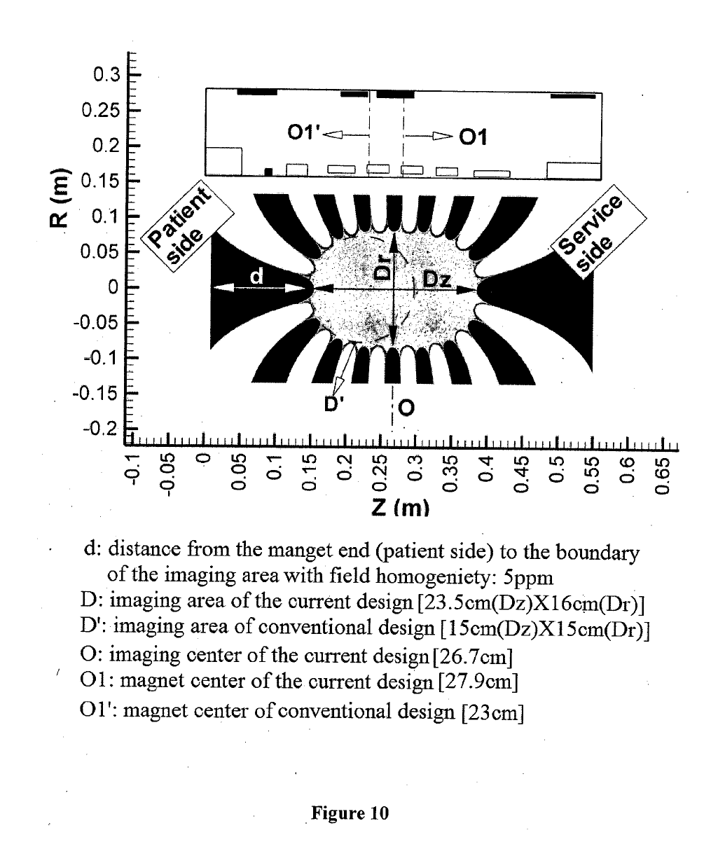

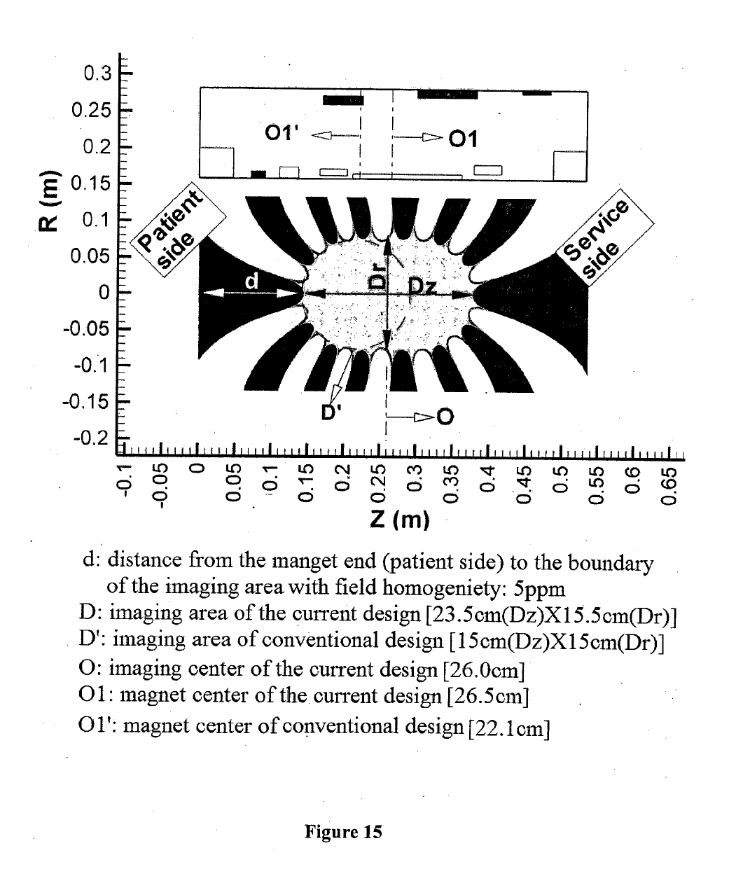

This example, shown schematically in FIGS. 10 and 15, illustrates a 3 T superconducting magnet design using a structure according to second and third embodiments of the invention.

As shown in FIG. 10, in the design version ‘a’, the coil structure is less than 55 cm in total length while a homogeneous dsv is generated: 23.5 cm along the axial direction and 7.5 cm in the radial direction, wherein the homogeneity of the dsv varies by less than 5 ppm over that volume. On the patient side of the primary layer, the coil next to the end coil is of opposite polarity to all others in the primary coil set. Six middle coils in this example are positioned in the centre region of the magnet. There is no negative coil next to the end coil on the service side. In this example, the axial distance between the magnet centre and the imaging centre is 1.2 cm. The coil structure again provides the advantage when combined with the other features of producing a relatively large and useful imaging region.

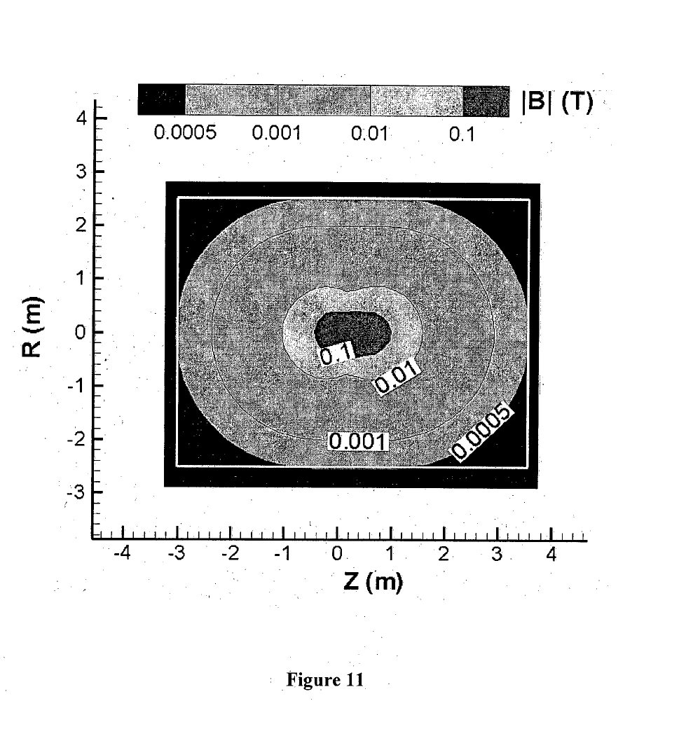

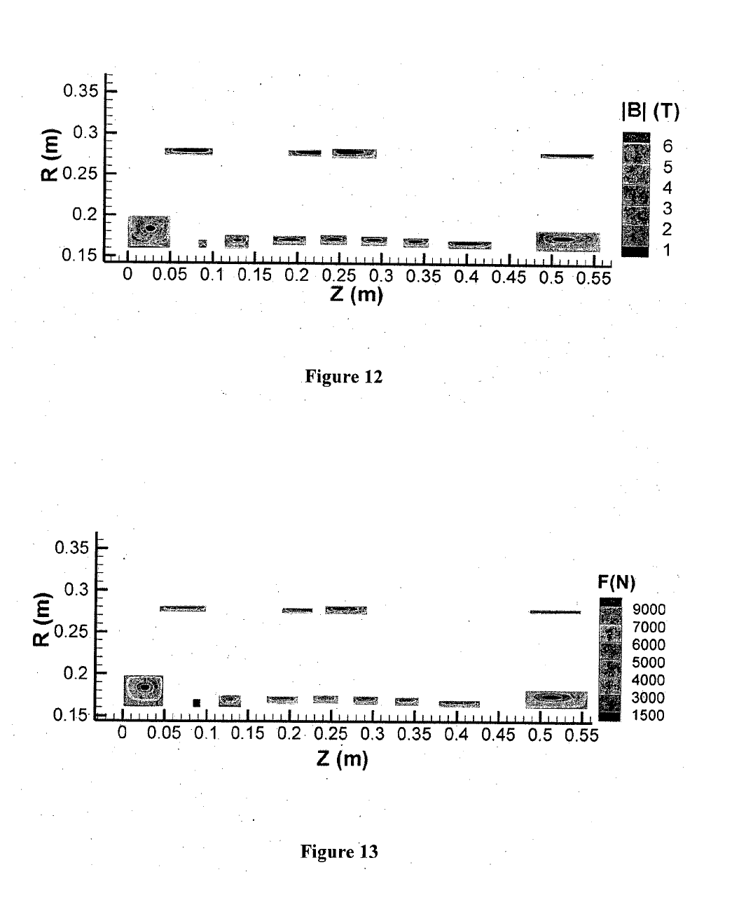

The stray fields in this magnet are well controlled, being approximately 3.6 m and 2.4 m in the axial and radial directions respectively as is shown in FIG. 11. The fields in the conductors shown in FIG. 12 are similar to that in example 1, and within capabilities of available superconducting wires.

The magnet of this example is well-suited for orthopaedic and similar applications, now at the higher field strength of three Tesla demonstrating the broad applicability of the proposed structure.

For comparative purposes, the magnet centre and dsv size of the conventional symmetric short-bore 3 T extremity magnet are illustrated in FIG. 10. By keeping d unchanged and relaxing the magnet length on the patient side about 9 cm, the dsv is significantly and beneficially extended in the axial direction from 15 cm to 23.5 cm (at 5 pmm homogeneity).

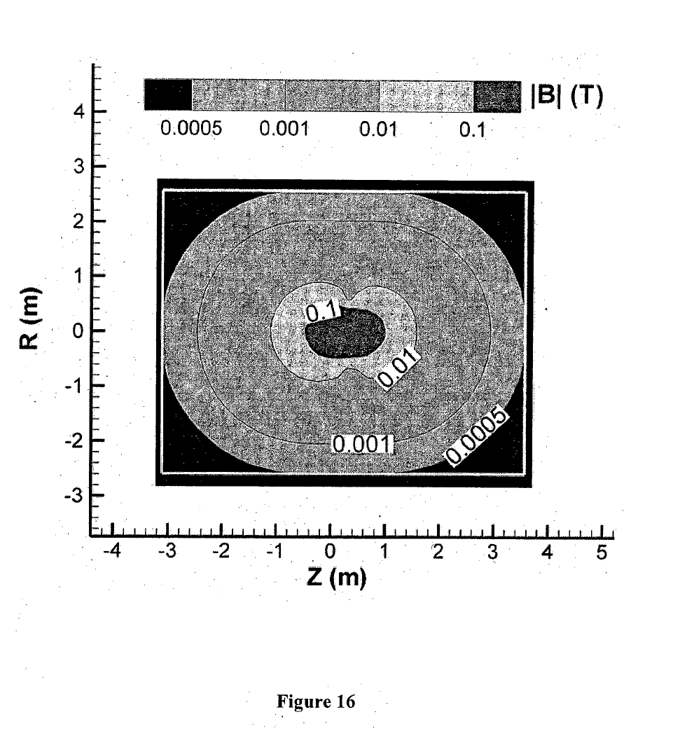

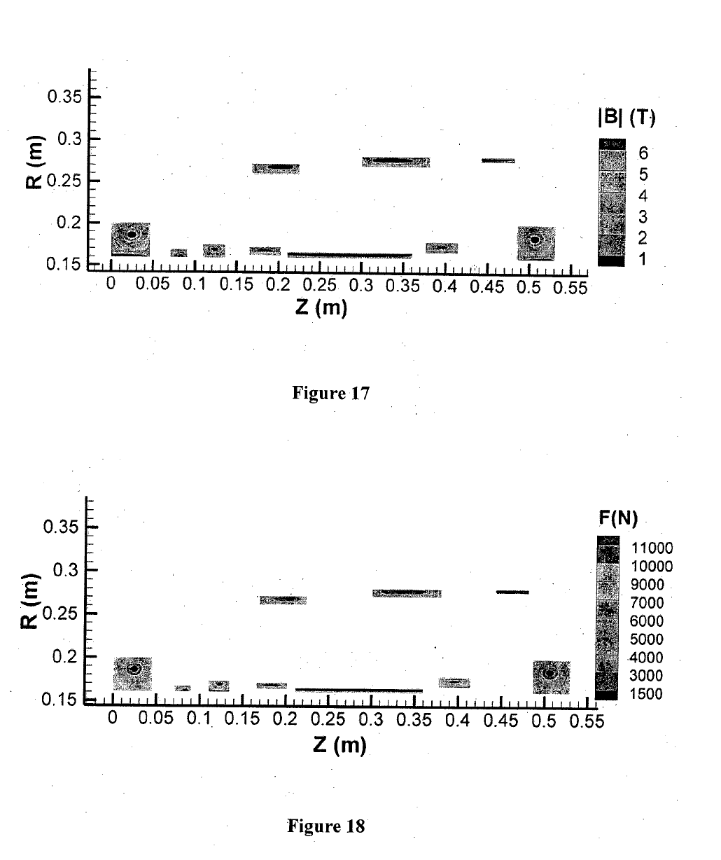

Similar results for the 3 T extremity case ‘b’ are shown in FIGS. 15 to 19. Compared with example 3 T extremity case ‘a’, this design uses less number of central positive coils (4 blocks) on the primary layer and less number of shielding coils (3 blocks) to produce a similar dsv. This clearly demonstrates the advantage of the coil structure of the invention for the same design target, one can produce an excellent dsv as long as the same invention concept is used. The increased dsv size relative to the shortest distance between the magnet end and dsv edge is of distinct benefit for extremity imaging. The subject can be comfortable during the procedure and a great range of imaging applications is possible.

In a further embodiment of the invention, force balancing is included so as to minimize the net forces on all of the coils in the magnet with specific attention being paid to the outermost coil on the primary.

As the magnet system is compact, the coils are necessarily in close proximity, and the magnetic forces that act on the superconducting windings can be very large. These forces can cause the superconducting alloys to perform below their rated properties or even to quench and cease superconducting. The consideration of magnetic forces in the design process is important for such a system and therefore in this embodiment automated force reduction is included in the design process, that is, the optimization includes Maxwell forces in the error function to be minimized. This permits an automated force reduction in the magnet designs while controlling the overall dimensions of the system [see Crozier S., Snape-Jenkinson C. J., Forbes L. K., The stochastic design of force-minimized compact magnets for high-field magnetic resonance imaging applications, IEEE Trans. Appl. Supercond., Vol. 11, No. 2, pp.: 4014-4022, 2001, the disclosure of which is incorporated herein by reference]. This improves the safety of the design and reduces the support requirements for the primary coil set in the axial direction.

The foregoing embodiments are intended to be illustrative of the invention, without limiting the scope thereof. The invention is capable of being practised with various modifications and additions as will readily occur to those skilled in the art.

For example, the coils may have different radii. In a head/whole body hybrid imaging system, the primary coils may have a smaller radius in the head imaging region, and larger radius in the body imaging region, but still use the design principles and inventive concept described above to achieve a larger dsv and smaller accessible distance.

We claim:

1-16. (canceled)

17. A superconducting magnet suitable for use in a magnetic resonance system, comprising
a primary coil structure having at least five primary coils positioned along an axis, including a first end coil adjacent a patient side of the magnet and a second end coil adjacent a service side of the magnet,
the magnet being capable of producing a magnetic field of at least 1.5 tesla which is substantially homogeneous over a predetermined imaging region,
wherein the primary coil structure has an asymmetric electromagnetic configuration, with the coil structure not being symmetric with respect to the axial centre of the imaging region and the primary coils on the patient side of the axial centre of the imaging region having larger total current than primary coils on the service side of the axial centre of the imaging region, and
wherein at least the primary coil which is next to first end coil is of opposite polarity to the first end coil.

18. A magnet as claimed in claim 17, further comprising a shielding coil structure having at least one shielding coil of greater diameter than the primary coils, the shielding coil structure being located radially outwardly of the primary coil structure.

19. A magnet as claimed in claim 17, wherein the magnet has an axial length less than 70 cm and is suitable for use in extremity imaging.

20. A magnet as claimed in claim 19 wherein the dimension of the imaging region along the radial direction is at least 10 cm.

21. A magnet as claimed in claim 17, wherein the magnet has an axial length less than 160 cm and is suitable for use in whole body imaging.

22. A magnet as claimed in claim 21 wherein the dimension of the imaging region along the radial direction is at least 40 cm.

23. A magnet as claimed in claim 17 wherein the cross-sectional dimension of the imaging region in axial direction (Dz) and the shortest distance between the edge of the imaging region and the end of the magnet on the patient side (d) satisfies the relationship: Dz/d=1˜2.

24. A magnet as claimed in claim 17 wherein the first and second end coils are of the same polarity.

25. A magnet as claimed in claim 17 wherein the primary coil structure includes at least three central coils in addition to the first and second end coils and the coil(s) of opposite polarity next to the end coil(s), the at least three central coils extending axially and defining an internal volume which covers the whole imaging region.

26. A magnetic resonance imaging system having a magnet as claimed in claim 17.

27. A method of designing a magnet as claimed in claim 17, wherein the method comprises the step of force balancing to minimize the net forces on at least the axial end coils in the primary coil structure.

28. A method as claimed in claim 27, wherein the step of force balancing comprises including Maxwell forces in an error function to be minimized.

29. A superconducting magnet for use in a magnetic resonance imaging system, comprising
a primary coil structure having at least five primary coils positioned along an axis, including a first end coil at a first axial end of the magnet and a second end coil at a second axial end of the magnet, the first and second coils being of the same polarity, and at least the primary coil which is next to first end coil is of opposite polarity to the first end coil,
the primary coil structure being configured to produce a magnetic field of at least 1.5 tesla which is substantially homogeneous over a predetermined imaging region located within the coil structure intermediate the first and second axial ends of the magnet, but located closer to the first axial end of the magnet than the second axial end, wherein the primary coils on one axial side of the axial centre of the imaging region have larger total current than primary coils on the other axial side of the axial centre of the imaging region, and wherein the imaging region is of ellipsoidal shape and wherein the cross-sectional dimension of the imaging region in axial direction (Dz) and the shortest distance between the edge of the imaging region and the first axial end of the magnet (d) satisfies the relationship: Dz/d=1˜2.

30. A superconducting magnet as claimed in claim 29 wherein the primary coil structure includes at least three central coils in addition to the first and second end coils and the coil of opposite polarity next to the first end coil, the at least three central coils extending axially and defining an internal volume which covers the whole imaging region.

31. A superconducting magnet as claimed in claim 29 wherein the magnet is capable of producing a magnetic field of at least 3.0 tesla.

32. A superconducting magnet as claimed in claim 29 further comprising a shielding coil structure located radially outwardly of the primary coil structure and extending substantially the whole axial length of the magnet.

33. A superconducting magnet as claimed in claim 29, wherein the magnet has an axial length less than 70 cm and is suitable for use in extremity imaging, and the dimension of the imaging region in the radial direction is at least 10 cm.

34. A superconducting magnet as claimed in claim 29, wherein the magnet has an axial length less than 160 cm and is suitable for use in whole body imaging, and the dimension of the imaging region in the radial direction is at least 40 cm.

35. A magnet as claimed in claim 17, wherein the imaging region is of ellipsoidal shape.

36. A magnet as claimed in claim 17, wherein the magnet is capable of producing a magnetic field of at least 3.0 tesla.
